(19) United States
(12) Patent Application Publication
(10) Pub. No.: US 2010/0220512 A1
(43) Pub. Date: Sep. 2, 2010

(54) PROGRAMMABLE POWER SOURCE USING ARRAY OF RESISTIVE SENSE MEMORY CELLS

(75) Inventors: Yiran Chen, Eden Prairie, MN (US); Insik Jin, Eagan, MN (US); Hai Li, Eden Prairie, MN (US); Dimitar V. Dimitrov, Edina, MN (US); Dexin Wang, Eden Prairie, MN (US)

Correspondence Address: Fellers, Snider, Blankenship, Bailey & Tippens, PC;(Seagate Technology LLC), 100 North Broadway, Suite 1700, Oklahoma City, OK, 73102-8820, US

(73) Assignee: SEAGATE TECHNOLOGY LLC, Scotts Valley, CA (US)

(21) Appl. No.: 12/396,126

(22) Filed: Mar. 2, 2009

(51) Int. Cl. G11C 11/00; G11C 5/14

(52) U.S. Cl. 365/148; 365/226

(57) ABSTRACT

Various embodiments of the present invention are generally directed to an apparatus comprising a programmable power source which uses an array of resistive sense memory cells, such as but not limited to STRAM or RRAM cells, to provide a controlled power bias to a load, such as but not limited to a micro-oscillator. In some embodiments, the programmable power source incorporates an array of serially connected resistive sense memory cells. A selectively controllable power level is applied by the programmable power source to a load in relation to a control input which selectively programs at least selected ones of the memory cells to a selected resistance state.

### BACKGROUND

Data storage devices generally operate to store and retrieve data in a fast and efficient manner. Some storage devices utilize a semiconductor array of solid-state memory cells to store individual bits of data. Such memory cells can be volatile or non-volatile. Volatile memory cells generally retain data stored in memory only so long as operational power continues to be supplied to the device. Non-volatile memory cells generally retain data stored in memory even in the absence of the application of operational power.

So-called resistive sense memory (RSM) cells can be configured to have different electrical resistances to store different logical states. The resistance of the cells can be subsequently detected during a read operation by applying a read current and sensing a voltage drop across the cell.

### SUMMARY

Various embodiments of the present invention are generally directed to an apparatus comprising a programmable power source which uses an array of resistive sense memory cells, such as but not limited to STRAM or RRAM cells, to provide a controlled power bias to a load, such as but not limited to a micro-oscillator.

In accordance with some embodiments, the apparatus generally comprises a programmable power source comprising an array of serially connected resistive sense memory cells, wherein a selectively controllable power level is applied by the programmable power source to a load in relation to a control input which selectively programs at least selected ones of the memory cells to a selected resistance state.

In accordance with other embodiments, the apparatus generally comprises a load, and first means for applying a selectively controllable power level to the load in relation to a resistance state programming control input.

These and various other features and advantages which characterize the various embodiments of the present invention can be understood in view of the following detailed discussion in view of the accompanying drawings.

### BRIEF DESCRIPTION OF THE DRAWINGS

FIG. 1 shows a functional representation of an exemplary programmable power source which provides a bias signal to a load in accordance with various embodiments of the present invention.

FIG. 2 is a functional representation of a data storage device to provide an exemplary environment in which various embodiments of the present invention can be advantageously embodied.

FIG. 3 is a simplified schematic depiction of a magnetic resistive element (RSE) based micro-oscillator.

FIG. 4 shows an exemplary construction for a resistive sense memory cell characterized as a spin-torque transfer random access memory (STTRAM or STRAM) cell.

FIG. 5 provides an exemplary construction for a resistive sense memory cell characterized as a resistive random access memory (RRAM) cell.

FIG. 6 is a functional block diagram showing an exemplary construction of the programmable power source of FIG. 1 to provide a controlled voltage bias to the micro-actuator of FIG. 3.

FIG. 7 provides an alternative configuration to that shown in FIG. 6.

FIG. 8 is a functional block diagram of another exemplary construction of the programmable power source of FIG. 1 to provide a controlled current bias to the micro-actuator of FIG. 3.

FIG. 9 sets forth another construction as an alternative to the construction exemplified in FIG. 8.

FIG. 10 provides a generalized arrangement that can be selectively programmed to emulate the various configurations of FIGS. 6-9.

### DETAILED DESCRIPTION

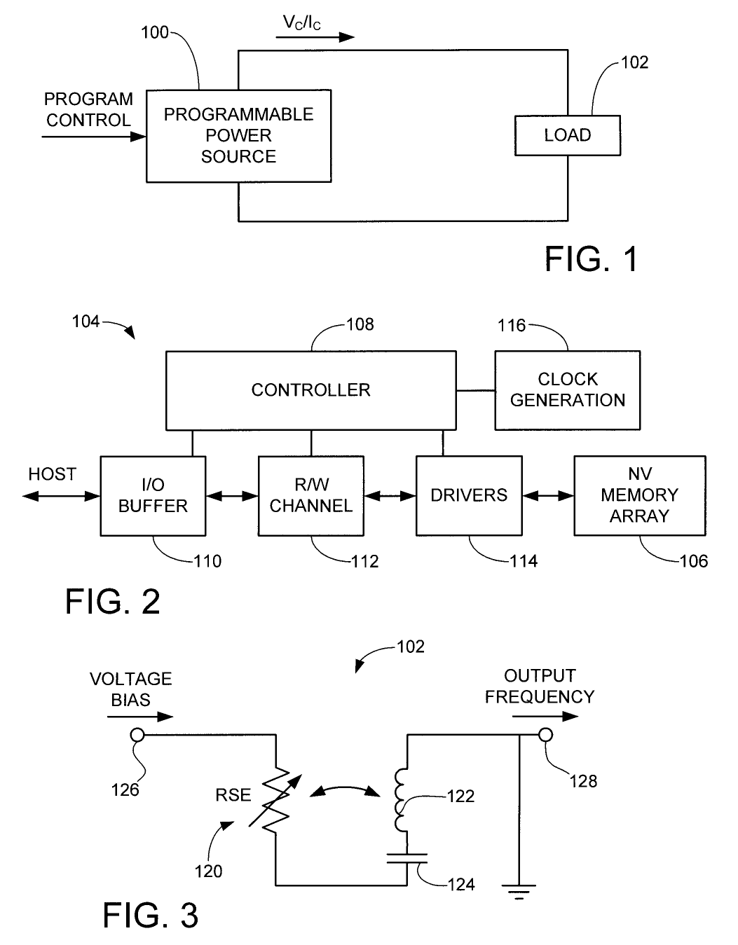

FIG. 1 shows a top level view of a programmable power source 100 constructed and operated in accordance with various embodiments of the present invention. The source 100 provides a selectively controllable power level to a load 102 in response to a programmable control input which selectively programs the source 100 as explained below. Depending on load characteristics, the selectively controllable power level can be an output voltage bias at a preselected voltage level, an output current bias at a preselected current level, etc.

FIG. 2 provides a generalized functional representation of a semiconductor data storage device 104 to provide an exemplary environment in which the circuitry of FIG. 1 can be embodied. Without limitation, the data storage device 104 is characterized as a non-volatile data storage device with a non-volatile memory array 106 of resistive sense memory cells. A controller 108 controls data transfers between the memory array 106 and a host via an input/output (I/O) buffer 110, a read/write channel 112 and drivers circuit 114.

A clock generation block 116 generates one or more high frequency clock signals for use by the device 104. It is contemplated that the clock generation block 116 of FIG. 2 incorporates the blocks of FIG. 1. In this case, the load 102 of FIG. 1 is characterized as a resistive sense element (RSE) based micro-oscillator, which outputs an oscillating signal with a frequency determined in relation to the power level supplied by the programmable power source 100.

FIG. 3 provides a schematic representation of the RSE based micro-oscillator 102 in accordance with some embodiments. An RSE element 120 is coupled to a feedback coil 122 through a capacitor 124, the latter of which form a feedback loop for the RSE 120. An initial perturbation is made through an input terminal 126 with a voltage bias from source 100 (FIG. 1).

The initial current rotates a free layer of the RSE 120 to increase the RSE resistance. As the RSE resistance increases, the current reduces. When the RSE resistance reaches its maximum value, the magnetic field of the feedback loop initiates a reduction in the RSE resistance. As a result, the current across the junction oscillates, providing an oscillating output at an output terminal 128. A number of different constructions of micro-oscillators are known in the art, so the example of FIG. 3 is merely illustrative and not limiting. While the micro-oscillator 102 of FIG. 3 has relatively high characteristic impedance and utilizes voltage bias input, it will be recognized that other micro-oscillator configurations can have relatively low characteristic impedance and utilize a current bias input.

In accordance with various embodiments, the programmable power source 100 of FIG. 1 is formed from an array of serially connected resistive sense memory (RSM) cells. These cells can have a similar construction to the RSE 120 of FIG. 3, or can take a different construction. RSM cells are also used to form the memory array 106 of FIG. 2 as well, although such is not necessarily required.

Advantages of RSM cells include the fact that no floating gate is provided, so no erase operation is necessary prior to the writing of new data to an existing set of cells as in the case with erasable non-volatile memory cell constructions such as EEPROM, flash, etc. Also, write and read power consumption requirements are substantially reduced, significantly faster write and read times can be achieved, and substantially no wear degradation is observed as compared to erasable cells, which generally have a limited write/erase cycle life.

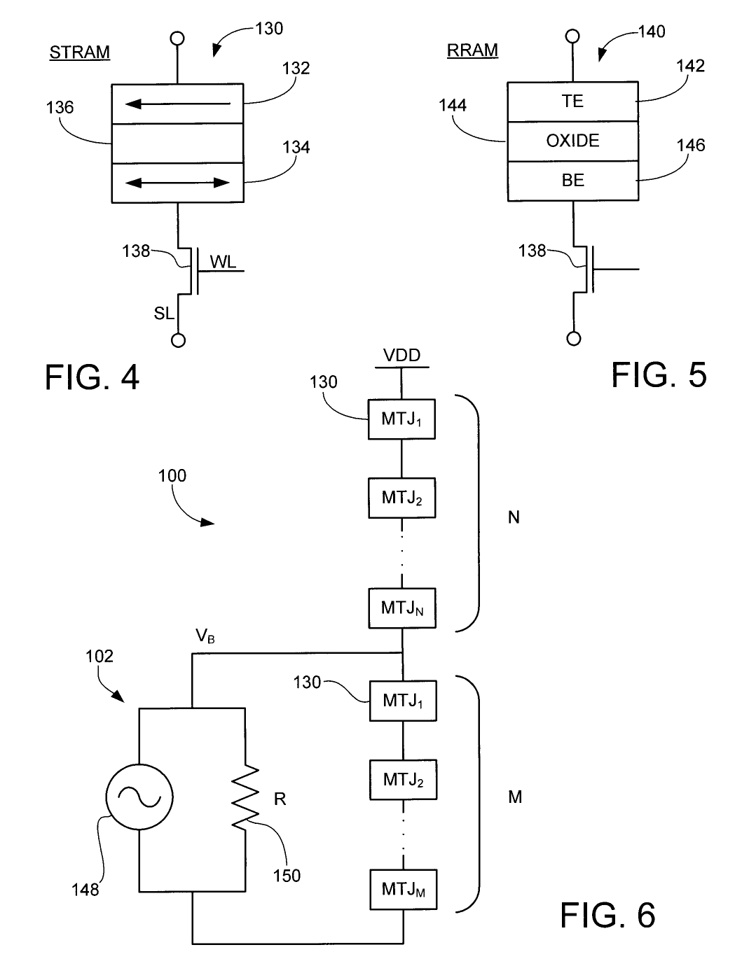

One exemplary construction for an RSM cell is shown at 130 in FIG. 4, characterized as a spin-torque transfer random access memory (STTRAM or STRAM) cell. A magnetic tunneling junction (MTJ) includes two ferromagnetic layers 132, 134 separated by an oxide barrier layer 136 (such as magnesium oxide, MgO). The resistance of the MTJ is determined in relation to the relative magnetization directions of the ferromagnetic layers 132, 134: when the magnetization is in the same direction (parallel), the MTJ is in a relatively low resistance state (R_{L}); when the magnetization is in opposite directions (anti-parallel), the MTJ is in a relatively high resistance state (R_{H}). This can be used to store data, in that the low resistance state can be assigned a first logical value, such as logical 0, and the high resistance state can be assigned a second logical value, such as logical 1.

In some embodiments, the magnetization direction of the reference layer 132 is fixed by coupling to a pinned magnetization layer (e.g., a permanent magnet, etc.), and the magnetization direction of the free layer 134 can be changed by passing a driving current polarized by magnetization in the reference layer 132. To read the logic state stored by the STRAM cell 130, a switching element 138 is placed into a conductive state (such as via a word line WL), and a relatively small current is passed through the MTJ from a bit line (BL) to a source line (SL). Because of the difference between the low and high resistances of the MTJ in the respective logical 0 and 1 states, the voltage at the bit line will be different, and this can be sensed by a sense amplifier (not shown).

Another exemplary construction for an RSM cell is shown at 140 in FIG. 5, characterized as a resistive random access memory (RRAM) cell. The RRAM 140 includes opposing, electrically conductive electrode layers 142, 146, and an intervening oxide layer 144. The electrode layers 142, 146 are formed of a suitable metal (such as a silver Ag based alloy), and the oxide layer 144 is formed of a suitable oxide (such as magnesium oxide MgO).

The oxide layer 144 is configured to have a nominally high resistance (e.g., R_{H}). The resistance of the oxide layer, however, can be lowered (e.g., R_{L}) through application of a relatively high write voltage across the RRAM cell 140. Such voltage generates lower resistance paths (filaments) as components of a selected electrode layer 142, 146 migrate into the oxide layer 144. The oxide layer 144 can be restored to its original, higher resistance state through application of a corresponding voltage of opposite polarity. As with the STRAM cell 130 in FIG. 4, a switching element 138 is incorporated into the RRAM cell 140 of FIG. 5 to facilitate individual selection of the cell.

FIG. 6 provides a functional representation of the programmable voltage source 100 of FIG. 1 in accordance with some embodiments. For the embodiment of FIG. 6, it will be contemplated that STRAM cells 130 as generally depicted in FIG. 4 will be used, although other configurations are contemplated including but not limited to RRAM cells as generally depicted in FIG. 5.

The arrangement of FIG. 6 comprises a first set of N STRAM cells 130 (identified as MTJ₁ through MTJ_{N}) in series with a second set of M STRAM cells 130 (identified as MTJ₁ through MTJ_{M}). It will be noted that the second set of M cells are further connected in parallel with the load 102, represented in FIG. 6 as an ideal frequency oscillator 148 with a resistor R 150 to denote a characteristic impedance.

Each of the MTJs in FIG. 6 can be individually and selectively programmed to either a low resistance or a high resistance as desired. Generally, the voltage bias V_{B} applied to the load 102 can be generally expressed as:

$${V}_{B} = VDD \frac{r ( M T J ( N ) )}{r ( M T J ( N ) ) + R ‖ r ( M T J ( M ) )} \qquad ( 1 )$$

where VDD is an input voltage applied to the programmable power source 100, r(MTJ(N)) represents the sum of the resistances of the first set of N cells, r(MTJ(M)) represents the sum of the resistances of the second set of M cells, and R∥r(MTJ(M)) denotes the resistance of the second set of M cells in parallel with resistance R. When the impedance 150 of the oscillator 102 is substantially greater than the resistance of the set of M cells, equation 1 can be rewritten as:

$${V}_{B} = VDD \frac{r ( M T J ( N ) )}{r ( M T J ( N ) ) + r ( M T J ( M ) )} \qquad ( 2 )$$

By adjusting the respective resistances of the N and M cells in FIG. 6, the voltage bias applied to the oscillator 102 can be provided from a low voltage V_{BL} of:

$${V}_{BL} = VDD \frac{{NR}_{H}}{{NR}_{H} + {MR}_{L}} \qquad ( 3 )$$

to a high voltage V_{BH} of:

$${V}_{BH} = VDD \frac{{NR}_{L}}{{NR}_{L} + {MR}_{H}} \qquad ( 4 )$$

where NR_{H} is the combined resistance of the N cells all set to a high resistance (R_{H}), NR_{L} is the combined resistance of the N cells set to low resistance (R_{L}), MR_{H} is the combined resistance of the M cells set to high resistance, and MR_{L} is the combined resistance of the M cells set to low resistance. It will be noted that the voltage bias V_{B} applied by the programmable power source 100 of FIG. 6 can be adjusted between V_{BL} and V_{BH} over about 2^{N+M} levels.

While operable, it will be noted that the configuration of FIG. 6 generally incurs a static current I_{S} of about:

$${I}_{S} = \frac{VDD}{r ( M T J ( N ) ) + r ( M T J ( M )} \qquad ( 5 )$$

To reduce the magnitude of this static current, the resistance of the MTJs or the respective numbers of the MTJs can be increased, as desired. It will be appreciated that increasing the number of MTJs provides higher selection capabilities (greater level resolution) as well as serves to amortize process variations related to the manufacturing of the device.

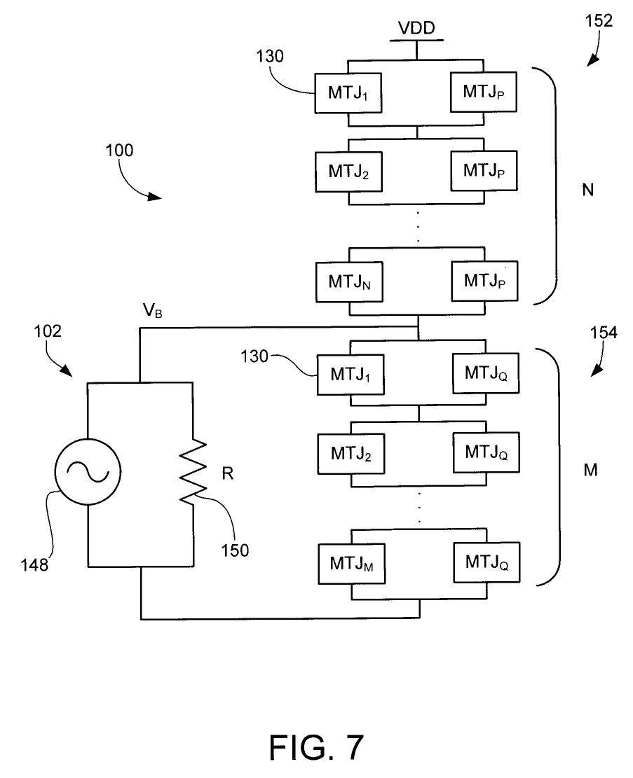

FIG. 7 shows an alternative configuration to that set forth by FIG. 6, in which additional MTJ cells are arranged in parallel to each of the M and N sets of cells in FIG. 6. More specifically, a first array 152 of N×P cells (N rows of P cells denoted MTJ₁ to MTJ_{P}) is coupled to a second array 154 of M×Q cells (M rows of Q cells denoted MTJ₁ to MTJ_{Q}). The number of P cells can be the same as the number of Q cells, or P and Q can be different values, as desired. It will be appreciated that the configuration of FIG. 7 can be set to match that of FIG. 6 if only one cell is activated in each of the M and N rows.

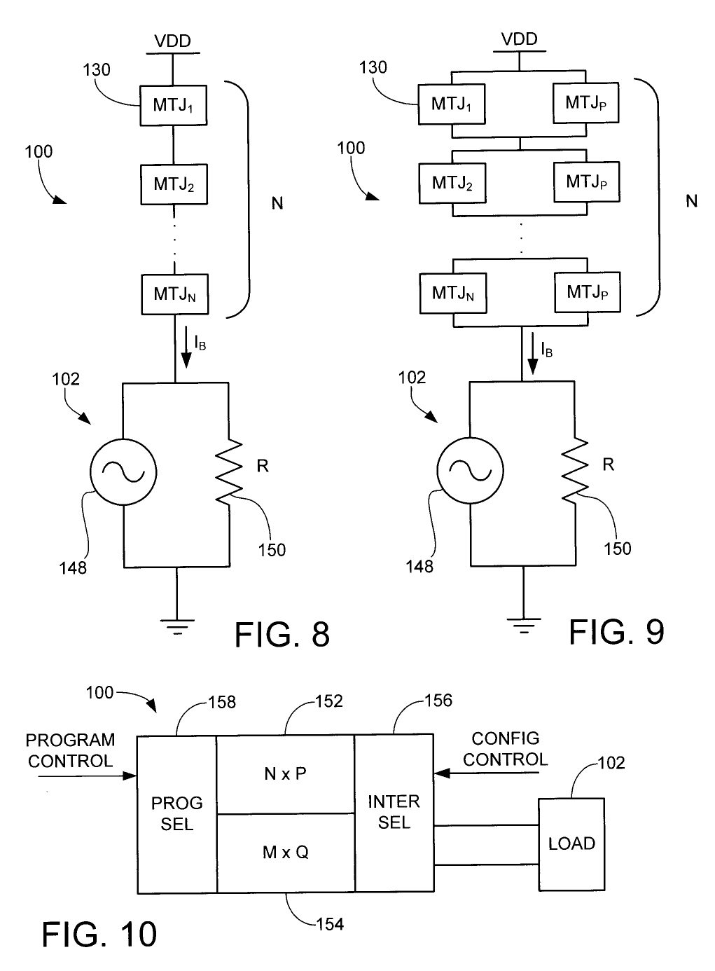

FIG. 8 provides an alternative construction for the programmable power source 100 which provides current biasing to the micro-oscillator 102. It is contemplated that the oscillator 102 is configured in FIG. 8 to have a relatively low characteristic impedance R.

The arrangement of FIG. 8 also places a set of N cells 130 in series with the micro-oscillator 102, but without the additional M cells of FIGS. 6 and 7. A current bias I_{B} can be expressed as:

$${I}_{B} = \frac{VDD}{r ( M T J ( N ) ) + R} \qquad ( 6 )$$

Since it is contemplated that the impedance R of the oscillator 102 will be substantially smaller than the combined resistance of the N cells r(MTJ(N)), equation (6) reduces to:

$${I}_{B} = \frac{VDD}{r ( M T J ( N ) )} \qquad ( 7 )$$

It follows that the current biasing applied by the programmable power source 100 in FIG. 8 can be adjusted over a range between high and low values I_{BH}, I_{BL} with about 2^{N} levels as follows:

$$\begin{matrix}{I}_{BH} = \frac{VDD}{{NR}_{L}} \\ and & ( 8 ) \\ {I}_{BL} = \frac{VDD}{{NR}_{H}} & ( 9 )\end{matrix}$$

As before, additional MTJs can be arranged in parallel with each of the N cells in FIG. 8, as depicted in FIG. 9, to provide further resolution and manufacturing process compensation.

A generalized structure for the programmable power source 100 is exemplified in FIG. 10. The respective MTJ arrays 152 (N×P) and 154 (M×Q) of FIG. 8 are shown in conjunction with a suitable interconnection selection circuit 156, which can be a mux or similar circuitry. Appropriate configuration inputs can be supplied to the selection circuit 156 to establish any of the above interconnection configurations of FIGS. 6-9 (or other related configurations as desired). Programming of the respective states of the individual MTJs is similarly carried out using a suitable programming selection circuit 158, which can also be a mux or similar circuitry.

Further, selection of an MTJ is carried out in some embodiments by activating a gate of a switching element associated with a particular MTJ with the interconnection selection circuit 156. A line driver component (not shown) of the programming selection circuit 158 subsequently can pass a write current through the MTJ to set a logical state. It can be appreciated that any number of MTJs along a row or column in an array can be selected and simultaneously programmed to a desired logical state.

In this way, the programmable power source 100 can be adaptively programmed for any number of different voltage and/or bias outputs. Similarly, for a given micro-oscillator 102, different frequency outputs can be achieved using different control inputs to the source 100. This provides a great deal of design and operational flexibility.

For example, in some embodiments, the programmable power source 100 as set forth in FIG. 10 is programmed with a first configuration to provide a first power bias signal for a first load which is selectively connected to the output of the power source. The same programmable power source 100 is then reprogrammed with a different, second configuration to provide a second power bias signal. This second power bias signal can be provided to a different, second load which is selectively connected to the power source 100 after disconnecting the first load from the power source. The first power bias signal can be a first type of bias signal, such as a controlled voltage, and the second power bias can be a second type of bias signal, such as a controlled current.

It will now be appreciated that various embodiments presented herein provide advantages. The use of RSM cells allow the cells to be quickly and easily programmed as desired to provide a selected output level without the need to erase or otherwise reconfigure various cells. A single programming step can be used to individually write the desired values any desired number of times, as wear issues are avoided. It is contemplated that in some embodiments, a table of values can be stored such as by the controller 108 (FIG. 2) and written to the programmable power source 100 to generate the corresponding voltage/current output. Such writing operations can include the overwriting of multiple existing values, including the writing of logical 0 state to some cells while concurrently writing logical 1 state to other cells.

While a micro-oscillator has been utilized in the various embodiments presented herein to provide an illustrative example of a suitable environment, it will be appreciated that any number of different types of electrical loads can be used.

Similarly, while various embodiments have provided the programmable power source 100 as a separate element to a data storage array (see e.g., elements 106, 116), it will be appreciated that, depending on the configuration of the data storage array, a selected number of memory cells from the array can be selectively activated as desired to provide the desired voltage or current bias. Accordingly, the output bias can be utilized in a number of other operations, including but not limited to the generation of a suitable voltage or bias current used to read the memory contents of another memory cell.

For purposes of the appended claims, the function of the recited “first means” will be understood to be carried out by resistive sense memory (RSM) cells as set forth in FIGS. 4-5 and as respectively interconnected as set forth in FIGS. 6-10.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. A programmable power source comprising an array of serially connected resistive sense memory cells configurable to provide an output responsive to a control input that programs at least one of the memory cells to a resistive state.

2. The apparatus of claim 1, wherein the selectively controllable power level comprises an output voltage bias at a preselected voltage level.

3. The apparatus of claim 1, wherein the selectively controllable power level comprises an output current bias as a preselected current level.

4. The apparatus of claim 1, wherein the array of serially connected resistive sense memory cells comprises a first set of N cells in series with a second set of M cells, wherein the first set of N cells are connected in series with the load, and wherein the second set of M cells are connected in parallel with the load.

5. The apparatus of claim 1, wherein the array of serially connected resistive sense memory cells comprises N cells connected in series with the load.

6. The apparatus of claim 5, wherein the array of serially connected resistive sense memory cells further comprises a plurality of cells connected in parallel with each of said N cells.

7. The apparatus of claim 1, wherein each memory cell of said array is selectively programmable to at least a first state of relatively low resistance and selectively programmable to at least a second state of relatively high resistance.

8. The apparatus of claim 7, wherein the control input is supplied by a controller which concurrently programs at least a first cell of said array in said first state and at least a second cell in said array in said second state.

9. The apparatus of claim 1, wherein each memory cell of said array is characterized as a spin-torque transfer random access memory (STRAM) cell.

10. The apparatus of claim 1, wherein each memory cell of said array is characterized as a resistive random access memory (RRAM) cell.

11. The apparatus of claim 1, wherein the array of memory cells comprises a first array of N rows of P memory cells, and wherein the programmable power source further comprises a second array of M rows of Q cells coupled to the first array and selection circuitry coupled to the first and second arrays, wherein the selection circuitry selectively interconnects the first and second arrays to respectively provide a selected voltage bias responsive to a first selection input thereto, and wherein the selection circuitry selectively interconnects the first and second arrays to respectively provide a selected current bias responsive to a different, second selection input thereto.

12. The apparatus of claim 1, wherein the load comprises a micro-oscillator without outputs an oscillating signal having a frequency selected in relation to said selectively controllable power level.

13. The apparatus of claim 1, wherein the programmable power source is incorporated into a semiconductor memory device comprising a non-volatile memory array of resistive sense memory cells.

14. An apparatus comprising a power source which is configured to output a selectively controllable power level in relation to a resistance state programming control input.

15. The apparatus of claim 14, wherein the first means comprises a programmable power source comprising an array of serially connected resistive sense memory cells, wherein the selectively controllable power level is applied by the programmable power source to the load in relation to said control input which selectively programs at least selected ones of the memory cells to a selected resistance state.

16. The apparatus of claim 15, wherein each memory cell of said array is alternately programmable to a first state of relatively low resistance and a second state of relatively high resistance.

17. The apparatus of claim 16, wherein the array of serially connected resistive sense memory cells comprises N cells connected in series with the load.

18. The apparatus of claim 17, wherein the array of serially connected resistive sense memory cells further comprises M cells connected in series with said M cells and connected in parallel with the load.

19. The apparatus of claim 16, wherein each memory cell of said array is characterized as a spin-torque transfer random access memory (STRAM) cell.

20. The apparatus of claim 16, wherein each memory cell of said array is characterized as a resistive random access memory (RRAM) cell.
